(19) United States
(12) Patent Application Publication
(10) Pub. No.: US 2012/0132244 A1
(43) Pub. Date: May 31, 2012

(54) SOLAR CELL MODULE WITH CURRENT CONTROL AND METHOD OF FABRICATING THE SAME

(75) Inventors: Yu-Ru Chen, Taichung City (TW); Chun-Ming Yeh, Taipei City (TW)

(73) Assignee: INDUSTRIAL TECHNOLOGY RESEARCH INSTITUTE, Hsinchu (TW)

(21) Appl. No.: 13/013,837

(22) Filed: Jan. 26, 2011

(30) Foreign Application Priority Data
Nov. 30, 2010 (TW) 99141527

(51) Int. Cl. H01L 31/05; H01L 31/18

(52) U.S. Cl. 136/244; 438/80; 257/E31.124

(57) ABSTRACT

A solar cell module with current control and a method of fabricating the same are provided. A plurality of rectifying diodes is formed simultaneously in series at a bus line formation area when solar cell units are fabricated. The rectifying diodes formed in series at the bus line formation area enables the solar cell to have the efficacy of current rectification when being shaded, and the output power of the solar cell is stabilized.

### CROSS-REFERENCE TO RELATED APPLICATION

This application claims the priority benefit of Taiwan application serial no. 99141527, filed on Nov. 30, 2010. The entirety of the above-mentioned patent application is hereby incorporated by reference herein and made a part of this specification.

### TECHNICAL FIELD

The disclosure relates to a solar cell (photovoltaic) module and a method for fabricating the same, and more particularly to a solar cell module with current control and a method for fabricating the same.

### BACKGROUND

Solar energy is a type of inexhaustible and pollution-free energy, and has been the focus of most attention in solving the current problems of shortage and pollution faced by the fossil fuel. Especially, solar cells become very important research topic at present, as they can directly convert solar energy into electricity.

Silicon solar cells are a type of common solar cells in the industry. The principle of silicon solar cells is to add some impurities into a high-purity semiconductor material (silicon) to exhibit different properties, for example, doping with Group III elements to form p-type semiconductors and doping with Group V elements to form n-type semiconductor, and the two p-n types semiconductors are combined together to form a p-n junction. When sunlight irradiates on a semiconductor of a p-n structure, electrons in the semiconductor may be excited by the energy provided by photons, so as to generate electron-hole pairs. The electrons and the holes are influenced by built-in potential, the holes move towards a direction of an electric field, and the electrons move towards an opposite direction. If the solar cell is connected to a load through a wire to form a loop, a current will flow through the load, which is the principle of power generation of the solar cell.

Due to advantages of low cost, easy large-scale production, and simple modularized process of thin film solar cells, thin film solar cells have become a new development direction. However, in a thin film solar cell module, solar cell units between bus lines at the front and the rear ends are connected in series, when part of the thin film solar cell module is in a shaded state, the generated current will reflux to a shaded area, thus resulting in current consumption and sharp decrease of output power of the module.

### SUMMARY

Accordingly, the present invention is directed to a solar cell module with current control, which has the efficacy of current rectification when the solar cell module is shaded and is capable of stabilizing the output power of the solar cell.

The present invention is also directed to a method for fabricating a solar cell module with current control, which is capable of fabricating a solar cell module having the efficacy of current rectification when the solar cell module is shaded and is capable of stabilizing the output power of the solar cell, and has a simple process without adding additional manufacturing cost.

A solar cell module with current control is introduced herein, which is disposed on a substrate including a bus line formation area and a solar cell unit area. The solar cell module includes a first electrode, a second electrode, and a photoelectric conversion layer. The first electrode has a plurality of first block electrodes and a plurality of first strip electrodes. The plurality of first block electrodes is disposed in parallel in a Y direction at the bus line formation area of the substrate, and a first X direction opening is disposed between two adjacent first block electrodes. The plurality of first strip electrodes is disposed in parallel in an X direction at the solar cell unit area of the substrate, and a first Y direction opening is disposed between two adjacent first strip electrodes. The second electrode has a plurality of second block electrodes and a plurality of second strip electrodes. The plurality of second block electrodes is disposed in parallel in the Y direction above the first block electrodes, and a second X direction opening is disposed between two adjacent second block electrodes. The plurality of second strip electrodes is disposed in parallel in the X direction above the first strip electrodes, and a second Y direction opening is disposed between two adjacent second strip electrodes. The second electrode and the first electrode are arranged in a manner such that the first X direction openings and second X direction openings are staggered in the Y direction and the first Y direction openings and the second Y direction openings are staggered in the X direction. The photoelectric conversion layer is disposed between the first electrode and the second electrode, a plurality of solar cell units is formed by the first electrode, the second electrode, and the photoelectric conversion layer at the solar cell unit area, and a plurality of rectifying diodes is formed by the first electrode, the second electrode, and the photoelectric conversion layer at the bus line formation area. The rectifying diodes and the solar cell units are connected in series in the X direction, and the rectifying diodes are connected in series in the Y direction.

A method for fabricating a solar cell module with current control is introduced herein. A first electrode material layer is formed on a substrate including a bus line formation area and a solar cell unit area. A part of the first electrode material layer is removed, so as to form a plurality of first X direction openings for spacing the first electrode material layer at the bus line formation area of the substrate into a plurality of first block electrodes and a plurality of first Y direction openings for spacing the first electrode material layer at the solar cell unit area of the substrate into a plurality of first strip electrodes, such that the first electrode material layer is made into the first electrode. A photoelectric conversion material layer is formed, so as to cover the first electrode and the substrate. A part of the photoelectric conversion material layer is removed, so as to form a plurality of second X direction openings for spacing the photoelectric conversion material layer into a plurality of block photoelectric conversion layers and a plurality of second Y direction openings for spacing the photoelectric conversion material layer into a plurality of strip photoelectric conversion layers, such that the photoelectric conversion material layer is made into a photoelectric conversion layer. A second electrode material layer is formed on the photoelectric conversion layer. A part of the second electrode material layer and the photoelectric conversion layer is removed, so as to form a plurality of third X direction openings for spacing the second electrode material layer into a plurality of second block electrodes and a plurality of third Y direction openings for spacing the second electrode material layer into a plurality of second strip electrodes, such that the second electrode material layer is made into a second electrode. The first X direction openings, the second X direction openings, and third X direction openings are staggered to one another, and the first Y direction openings, the second Y direction openings, and the third Y direction openings are staggered to one another, such that a plurality of solar cell units is formed by the first electrode, the second electrode, and the photoelectric conversion layer at the solar cell unit area, a plurality of rectifying diodes is formed by the first electrode, the second electrode, and the photoelectric conversion layer at the bus line formation area, the rectifying diodes and the solar cell units are connected in series in the X direction, and the rectifying diodes are connected in series in the Y direction.

In the solar cell module with current control of the present invention, as a plurality of rectifying diodes is formed in series at the bus line formation area, the rectifying diodes enable the solar cell module to have the efficacy of current rectification when the solar cell module is shaded, and the output power of the solar cell is stabilized.

According to the method for fabricating a solar cell module with current control, when fabricating solar cell units, a plurality of rectifying diodes is formed in series at the bus line formation area at the same time, so the process is simple, and no additional manufacturing cost is added.

In order to make the aforementioned and other objectives and advantages of the present invention comprehensible, embodiments accompanied with figures are described in detail below.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 3A are top views illustrating a process of a method for fabricating a solar cell module with current control according to an exemplary embodiment of the present invention.

FIGS. 1B to 3B are schematic cross-sectional views along line A-N in FIGS. 1A to 3A.

FIGS. 1C to 3C are schematic cross-sectional views along line B-B′ in FIGS. 1A to 3A.

FIG. 4 is a circuit diagram of a solar cell module with current control according to an exemplary embodiment of the present invention.

### DETAILED DESCRIPTION OF DISCLOSED EMBODIMENTS

An embodiment provides a method for fabricating a solar cell module with current control.

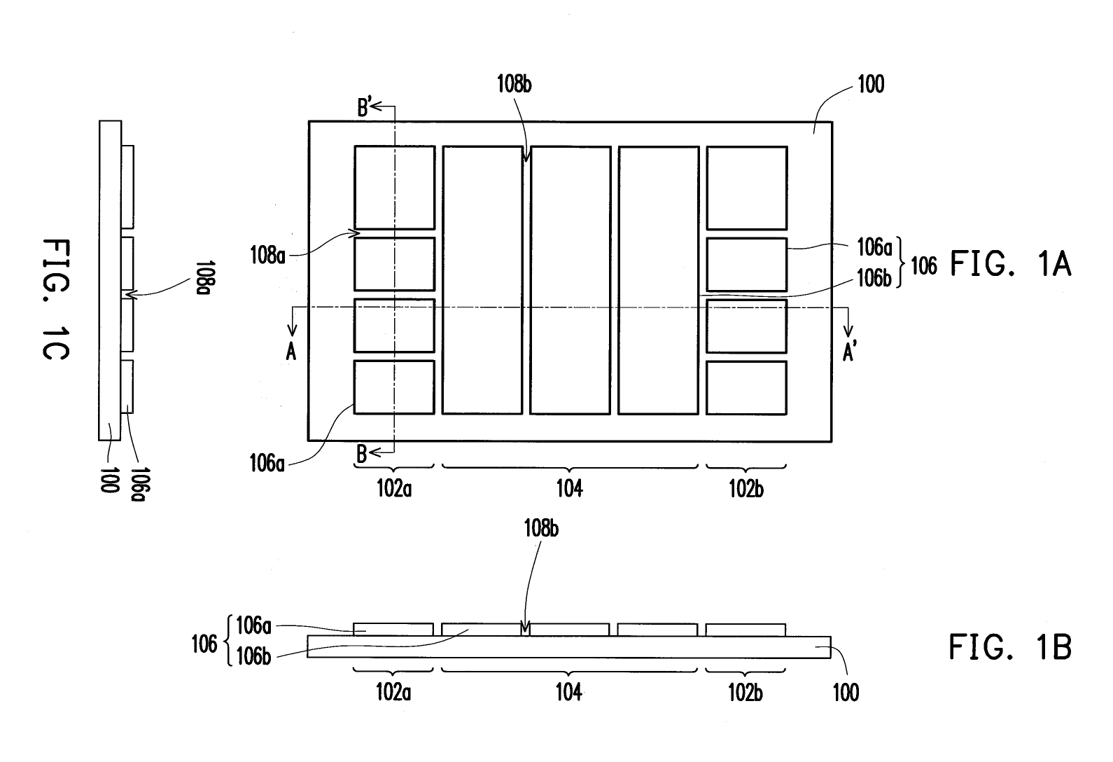

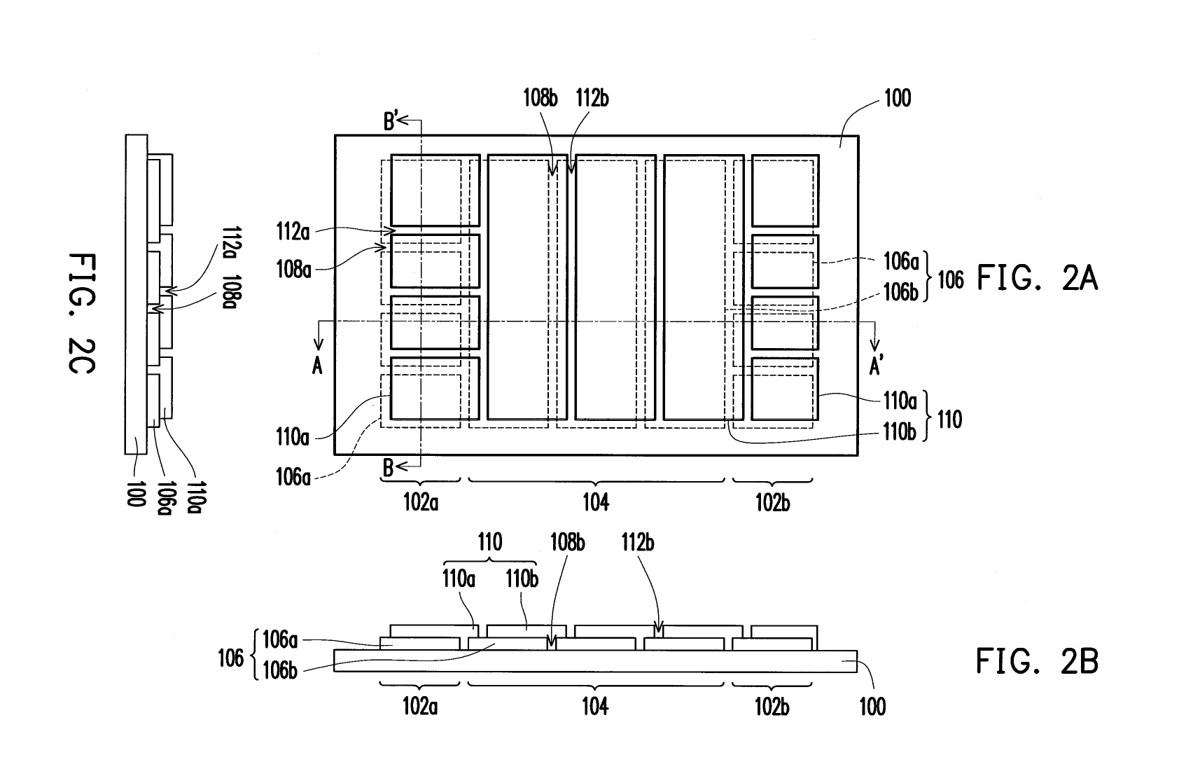

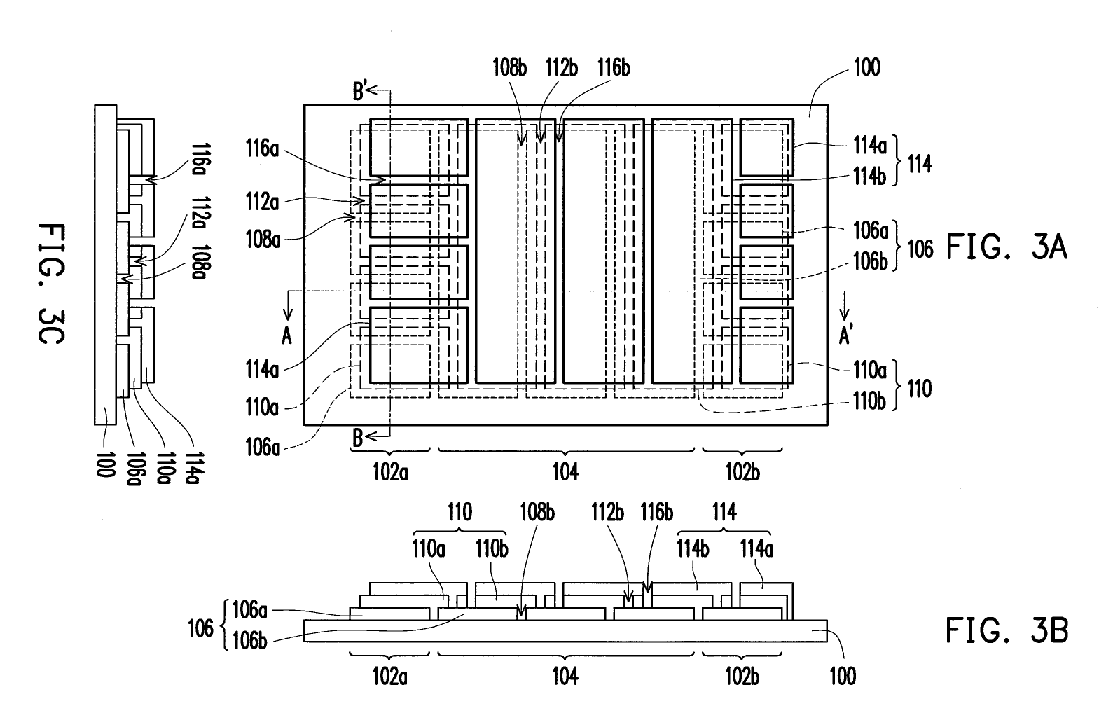

FIGS. 1A to 3A are top views illustrating a process of a method for fabricating a solar cell module with current control according to an exemplary embodiment of the present invention. FIGS. 1B to 3B are schematic cross-sectional views along line A-A′ in FIGS. 1A to 3A, and FIGS. 1C to 3C are schematic cross-sectional views along line B-B′ in FIGS. 1A to 3A

First, referring to FIGS. 1A to 1C, a substrate 100 is provided. The material of the substrate 100 is, for example, glass or resin. The substrate 100 is, for example, divided into bus line formation areas 102a and 102b and a solar cell unit area 104. The solar cell unit area 104 is located between the bus line formation areas 102a and 102b.

Next, an electrode layer 106 is formed on the substrate 100. The electrode layer 106 has a plurality of block electrodes 106a and a plurality of strip electrodes 106b.

The plurality of block electrodes 106a is disposed in parallel in a Y direction at the bus line formation areas 102a and 102b of the substrate 100, and an X direction opening 108a is disposed between two adjacent block electrodes 106a.

A plurality of strip electrodes is disposed in parallel in an X direction at the solar cell unit area 104 of the substrate 100, and a Y direction opening 108b is disposed between two adjacent strip electrodes 106b.

A method for forming the electrode layer 106 includes, for example, first forming an electrode material layer (not shown). The electrode material layer is a transparent conductive oxide (TCO) thin film, and the material is, for example, zinc oxide (ZnO), tin dioxide (SnO₂), indium tin oxide (ITO), or indium oxide (In₂O₃). The electrode material layer is prepared by using, for example, a chemical vapor deposition (CVD), a sputtering, or other suitable methods.

Definitely, after forming the electrode material layer, in order to improve the efficiency of the cell, textured surface treatment may be performed on the electrode material, so as to reduce the amount of reflected light. The textured surface treatment will result in uneven surface which scatters the light, thus reducing the reflection of the incident light and increasing the travel distance of the incident light in the photoelectric conversion layer. Generally, the surface of the electrode material is made into U-shaped notches, a pyramid structure (not shown) or a reversed pyramid structure, or a complex textured surface.

Then, a part of the electrode material layer is removed, so as to form a plurality of X direction openings 108a for spacing the bus line formation areas 102a and 102b at the electrode material layer of the substrate 100 into a plurality of block electrodes 106a and a plurality of Y direction openings 108b for spacing the electrode material layer at the solar cell unit area 104 of the substrate 100 into a plurality of strip electrodes 106b. Furthermore, a method for forming the X direction openings 108a and the Y direction openings 108b is, for example, removing part of the electrode material layer by using a laser scribing process.

Thereafter, referring to FIGS. 2A to 2C, a photoelectric conversion layer 110 is formed on the substrate 100. A method for forming the photoelectric conversion layer 110 includes, for example, first forming a photoelectric conversion material layer. The photoelectric conversion material layer covers the transparent substrate 100 and the electrode 106. The photoelectric conversion material layer is, for example, a single layer structure or a stacked layer structure. The material of the photoelectric conversion material layer is, for example, silicon or alloys thereof. The photoelectric conversion material layer is prepared by using, for example, a CVD or other suitable methods. Additionally, it should be noted that, the silicon alloys refer to alloys formed by adding atoms such as hydrogen (H), fluorine (F), chlorine (Cl), germanium (Ge), oxygen (O), carbon (C), Boron (B), Phosphate (P) or nitrogen (N) into silicon.

A part of the photoelectric conversion material layer is removed, so as to form a plurality of X direction openings 112a for spacing the photoelectric conversion material layer into a plurality of block photoelectric conversion layers 110a and a plurality of Y direction openings 112b for spacing the photoelectric conversion material layer into a plurality of strip photoelectric conversion layers 110b, such that the photoelectric conversion material layer is made into the photoelectric conversion layer 110. The X direction openings 108a and the X direction openings 112a are staggered in the Y direction, and the Y direction openings 108b and the Y direction openings 112b are staggered in the X direction. Furthermore, a method for forming the X direction openings 112a and the Y direction openings 112b is, for example, removing a part of the photoelectric conversion material layer by using a laser scribing process.

Next, referring to FIGS. 3A to 3C, an electrode layer 114 is formed on the photoelectric conversion layer 110. The electrode layer 114 has a plurality of block electrodes 114a and a plurality of strip electrodes 114b.

The plurality of block electrodes 114a is disposed in parallel in the Y direction above the photoelectric conversion layer 110, and an X direction opening 116a is disposed between two adjacent block electrodes 114a.

The plurality of strip electrodes 114b is disposed in parallel in the X direction above the photoelectric conversion layer 110, and a Y direction opening 116b is disposed between two adjacent strip electrodes 114b.

The X direction openings 116a, the X direction openings 112a, and the X direction openings 108a are staggered in the Y direction, and Y direction openings 116b, the Y direction openings 112b, and the Y direction openings 108b are staggered in the X direction.

A method for forming the electrode layer 114 includes, for example, first forming an electrode material layer (not shown). The electrode material layer is formed by, for example, a TCO layer or a metal layer. The material of the TCO layer includes zinc oxide (ZnO), tin dioxide (SnO₂), indium tin oxide (ITO), or indium oxide (In₂O₃). The material of the metal layer is aluminum (Al), silver (Ag), copper (Cu), molybdenum (Mo), or alloys thereof. The electrode material layer 418 is prepared by using, for example, a CVD, a sputtering, or other suitable methods.

Then, a part of the electrode material layer and the photoelectric conversion layer 110 is removed, till the surface of the electrode 106 is exposed, so as to form a plurality of X direction openings 116a for spacing the electrode material layer into a plurality of block electrodes 114a and a plurality of Y direction openings 116b for spacing the electrode material layer into a plurality of strip electrodes 114b. Furthermore, a method for forming the X direction openings 116a and the Y direction openings 116b is, for example, removing a part of the electrode material layer and the photoelectric conversion layer 110 by using a laser scribing process.

Referring to FIGS. 3A to 3C, the solar cell module with current control of the present invention is, for example, disposed on the substrate 100. The solar cell module with current control is, for example, formed by the electrode 106, the electrode 114, and the photoelectric conversion layer 110.

The electrode 106 includes a plurality of block electrodes 106a and a plurality of strip electrodes 106b. The plurality of block electrodes 106a is disposed in parallel in the Y direction at the bus line formation areas 102a and 102b of the substrate 100, and an X direction opening 108a are disposed between two adjacent block electrodes 106a. The plurality of strip electrodes 106b is disposed in parallel in the X direction at the solar cell unit area 104 of the substrate 100, and a Y direction openings 108b is disposed between two adjacent strip electrodes 106b.

The electrode 114 includes a plurality of block electrodes 114a and a plurality of strip electrodes 114b. The plurality of block electrodes 114a is disposed in parallel in the Y direction above the block electrodes 106a, and an X direction opening 116a is disposed between two adjacent block electrodes 114a. The plurality of strip electrodes 114b is disposed in parallel in the X direction above the strip electrodes 106b, and a Y direction opening 116b is disposed between two adjacent strip electrodes 114b. The electrode 106 and the electrode 114 are disposed in a manner such that the X direction openings 108a and the X direction openings 116a are staggered in the Y direction and the Y direction openings 108b and the Y direction openings 116b are staggered in the X direction.

The photoelectric conversion layer 110 is disposed between the electrode 106 and the electrode 114. A plurality of solar cell units is formed by the electrodes 106b, the photoelectric conversion layer 110b and the electrodes 114b at the solar cell unit area 104, and a plurality of rectifying diodes is formed by the electrodes 106a, the photoelectric conversion layer 110a, and the electrodes 114a at the bus line formation areas 102a and 102b. The rectifying diodes and the solar cell units are connected in series in the X direction, and the rectifying diodes are connected in series in the Y direction.

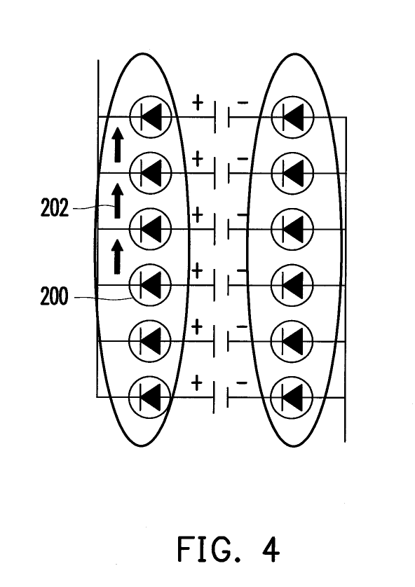

FIG. 4 is a circuit diagram of a solar cell module with current control according to an exemplary embodiment of the present invention.

As shown in FIG. 4, rectifying diodes 200 enable the solar cell module to have the efficacy of current rectification when the solar cell module is shaded, such that a current 202 will not reflux to a shaded area, and the output power of the solar cell is stabilized.

In view of the above, according to the method for fabricating a solar cell module with current control of the present invention, when fabricating solar cell units, a plurality of rectifying diodes is formed in series at the bus line formation area at the same time, such that the process is simple, and no additional manufacturing cost is added. Moreover, in the solar cell module with current control of the present invention, as a plurality of rectifying diodes is formed in series at the bus line formation area, and the rectifying diodes enable the solar cell module to have the efficacy of current rectification when the solar cell module is shaded, the output power of the solar cell is stabilized.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A solar cell module with current control, disposed on a substrate having a bus line formation area and a solar cell unit area, comprising:
a first electrode, comprising:
a plurality of first block electrodes, disposed in parallel in a Y direction on the bus line formation area of the substrate, wherein a first X direction opening is disposed between two adjacent first block electrodes;
a plurality of first strip electrodes, disposed in parallel in an X direction on the solar cell unit area of the substrate, wherein a first Y direction opening is disposed between two adjacent first strip electrodes;
a second electrode, comprising:
a plurality of second block electrodes, disposed in parallel in the Y direction above the first block electrodes, wherein a second X direction opening is disposed between two adjacent second block electrodes;
a plurality of second strip electrodes, disposed in parallel in the X direction above the first strip electrodes, wherein a second Y direction opening is disposed between two adjacent second strip electrodes, the second electrode and the first electrode are arranged in a manner such that the first X direction openings and the second X direction openings are staggered in the Y direction and the first Y direction openings and the second Y direction openings are staggered in the X direction; and
a photoelectric conversion layer, disposed between the first electrode and the second electrode, wherein a plurality of solar cell units is formed by the first electrode, the second electrode, and the photoelectric conversion layer at the solar cell unit area, and a plurality of rectifying diodes is formed by the first electrode, the second electrode, and the photoelectric conversion layer at the bus line formation area, the rectifying diodes and the solar cell units are connected in series in the X direction, and the rectifying diodes are connected in series in the Y direction.

2. The solar cell module with current control according to claim 1, wherein the first electrode is made of a transparent conductive oxide (TCO) layer.

3. The solar cell module with current control according to claim 2, wherein a material of the TCO layer is selected form a group consisting of zinc oxide (ZnO), tin dioxide (SnO₂), indium tin oxide (ITO), and indium oxide (In₂O₃).

4. The solar cell module with current control according to claim 1, wherein the photoelectric conversion layer has a stacked layer structure.

5. The solar cell module with current control according to claim 1, wherein a material of the photoelectric conversion layer is selected form a group consisting of silicon and alloys thereof.

6. The solar cell module with current control according to claim 1, wherein the second electrode is selected form a group consisting of a TCO layer and a metal layer.

7. The solar cell module with current control according to claim 6, wherein a material the TCO layer is selected form a group consisting of zinc oxide (ZnO), tin dioxide (SnO₂), indium tin oxide (ITO), and indium oxide (In₂O₃), and a material of the metal layer is selected form a group consisting of aluminum (Al), silver (Ag), copper (Cu), molybdenum (Mo), and alloys thereof.

8. A method for fabricating a solar cell module with current control, comprising:
forming a first electrode material layer on a substrate having a bus line formation area and a solar cell unit area;
removing a part of the first electrode material layer, so as to form a plurality of first X direction openings for spacing the first electrode material layer on the bus line formation area of the substrate into a plurality of first block electrodes and a plurality of first Y direction openings for spacing the first electrode material layer on the solar cell unit area of the substrate into a plurality of first strip electrodes, such that the first electrode material layer is made into a first electrode;
forming a photoelectric conversion material layer, so as to cover the first electrode and the substrate;
removing a part of the photoelectric conversion material layer, so as to form a plurality of second X direction openings for spacing the photoelectric conversion material layer into a plurality of block photoelectric conversion layers and a plurality of second Y direction openings for spacing the photoelectric conversion material layer into a plurality of strip photoelectric conversion layers, such that the photoelectric conversion material layer is made into a photoelectric conversion layer;
forming a second electrode material layer on the photoelectric conversion layer;
removing a part of the second electrode material layer and the photoelectric conversion layer, so as to form a plurality of third X direction openings for spacing the second electrode material layer into a plurality of second block electrodes and a plurality of third Y direction openings for spacing the second electrode material layer into a plurality of second strip electrodes, such that the second electrode material layer is made into a second electrode;
wherein the first X direction openings, the second X direction openings, and the third X direction openings are staggered to one another, and the first Y direction openings, the second Y direction openings, and the third Y direction openings are staggered to one another, such that a plurality of solar cell units is formed by the first electrode, the second electrode, and the photoelectric conversion layer at the solar cell unit area, a plurality of rectifying diodes is formed by the first electrode, the second electrode, and the photoelectric conversion layer at the bus line formation area, the rectifying diodes and the solar cell units are connected in series in the X direction, and the rectifying diodes are connected in series in the Y direction.

9. The method for fabricating a solar cell module with current control according to claim 8, wherein the first Y direction openings, the second Y direction openings, and the third Y direction openings and the first X direction openings, the second X direction openings, and the third X direction openings are formed through laser scribing.

10. The method for fabricating a solar cell module with current control according to claim 8, wherein the first electrode material layer is made of a transparent conductive oxide (TCO) layer.

11. The method for fabricating a solar cell module with current control according to claim 10, wherein a material of the TCO layer is selected form a group consisting of zinc oxide (ZnO), tin dioxide (SnO₂), indium tin oxide (ITO), and indium oxide (In₂O₃).

12. The method for fabricating a solar cell module with current control according to claim 8, wherein the photoelectric conversion layer is a single layer structure or a stacked layer structure.

13. The method for fabricating a solar cell module with current control according to claim 8, wherein a material of the photoelectric conversion layer is selected form a group consisting of silicon and alloys thereof.

14. The method for fabricating a solar cell module with current control according to claim 8, wherein the second electrode material layer is selected form a group consisting of a TCO layer and a metal layer.

15. The method for fabricating a solar cell module with current control according to claim 14, wherein a material of the TCO layer is selected form a group consisting of zinc oxide (ZnO), tin dioxide (SnO₂), indium tin oxide (ITO), or indium oxide (In₂O₃); and a material of the metal layer comprises aluminum (Al), silver (Ag), copper (Cu), molybdenum (Mo), and alloys thereof.
